(19) United States
(12) Patent Application Publication
(10) Pub. No.: US 2009/0140397 A1
(43) Pub. Date: Jun. 4, 2009

(54) SEMICONDUCTOR DEVICE AND MANUFACTURING METHOD THEREFOR

(75) Inventor: Mitsunari SUKEKAWA, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 12/325,651

(22) Filed: Dec. 1, 2008

(30) Foreign Application Priority Data
Dec. 3, 2007 (JP) 2007-312823

(51) Int. Cl. H01L 23/48

(52) U.S. Cl. 257/637; 257/E23.01

(57) ABSTRACT

A semiconductor device includes capacitors formed on the surface of an interlayer insulating film in connection with capacitive contact plug, wherein capacitors are constituted of base-side lower electrode films having hollow-pillar shapes, metal plugs embedded in hollows of base-side lower electrode films, and top-side lower electrode films having hollow-pillar shapes engaged with the upper portions of the hollows as well as dielectric films and upper electrode films which are sequentially laminated so as to cover the peripheral surfaces of the base-side and top-side lower electrode films and the interior surfaces of the top-side lower electrode films. Side walls are further formed to connect together the adjacent base-side lower electrode films. Thus, it is possible to control the aspect ratio of a capacitor hole for embedding the metal plug from being excessively increased, and it is possible to increase the capacitive electrode area of each capacitor.

### BACKGROUND OF THE INVENTION

1. Field of the Invention

The present invention relates to semiconductor devices including memory cells such as dynamic random-access memories and manufacturing methods therefor.

The present application claims priority on Japanese Patent Application No. 2007-312823, the content of which is incorporated herein by reference.

2. Description of Related Art

Various technologies regarding semiconductor devices including dynamic random-access memories have been developed and disclosed in various documents such as Patent Documents 1-3.
Patent Document 1: Japanese Unexamined Patent Application Publication No. H11-204753
Patent Document 2: Japanese Unexamined Patent Application Publication No. 2006-324363
Patent Document 3: Japanese Unexamined Patent Application Publication No. 2007-81189

A typical example of a dynamic random-access memory (DRAM) includes a plurality of memory cells which are constituted of transistors and capacitors, wherein capacitors are formed using lower electrodes, dielectric films, and upper electrodes. As the size of the DRAM becomes smaller, the overall area occupied by capacitors becomes correspondingly smaller. Using the three-dimensional structure is an effective way to increase the surface area of electrodes included in capacitors and to thereby secure an adequate amount of electrostatic capacitance in the limited area of the DRAM. Due to recent progresses for further refining the structures of semiconductors, it becomes difficult to secure an adequate area for electrodes in the DRAM.

According to the generally-known formation method of capacitors for use in a DRAM, capacitor holes (or through-holes) are formed by way of dry etching after the formation of interlayer insulating films; then, lower electrodes, dielectric films, and upper electrodes are sequentially formed inside capacitor holes. Refining the structure of the DRAM increases the effective aspect ratios of capacitor holes and makes it difficult to perform dry etching to form capacitor holes. This is because the reach probability of etching gas becomes lower and results in a reduction of the etching speed in progression of etching (for forming capacitor holes). When effective aspect ratios becomes extremely high, they speed up a reduction of ion energy and a reduction of the etching speed, thus eventually causing an etch-stop event in which etching reaction stops progressing.

Another technology for enlarging the area used for capacitive lower electrodes is developed to cope with the above drawback. This technology will be described in conjunction with FIGS. 13 to 15.

First, as shown in FIG. 13, capacitive electrode pads 32 composed of polysilicon are formed on an interlayer insulating film 30 having capacitive contact holes 31; a silicon nitride film 33 serving as an etching stopper is formed to cover the capacitive electrode pads 32; and then, an interlayer insulating film 34 is formed on the silicon nitride film 33.

Subsequently, as shown in FIG. 14, capacitor holes (or through-holes) 35 are formed in the interlayer insulating film 34 and the silicon nitride film 33 by way of dry etching, thus exposing the capacitive electrode pads 32. In addition, the capacitive electrode pads 32 are removed by way of wet etching, thus exposing the capacitive contact plugs 31.

Thereafter, as shown in FIG. 15, lower electrodes 36, capacitive films 37, and upper electrodes 38 are formed in the capacitor holes 35, thus forming common electrodes 39 and 40 on the interlayer insulating film 34. Since the capacitive electrodes pads 32 are formed in advance and are then removed by way of dry etching, it is possible to expand the lower portions of the lower electrodes 36, thus enlarging the overall area used for the lower electrodes 36.

The present inventor has recognized that the above method for enlarging the overall area used for the lower electrodes 36 cannot be adequately applied to crown capacitors. In order to form crown capacitors, it is necessary to partially remove the interlayer insulating film 30 so as to expose the peripheral surfaces of the lower electrodes 36, whereas since the lower portions of the lower electrodes 36 are peripherally covered with the silicon nitride film 33, it is difficult to use the entirety of the peripheral surfaces of the lower electrodes 36 as capacitive electrodes.

### SUMMARY

The present invention seeks to solve the above problem, or to improve upon the problem at least in part.

In one embodiment, there is provided a semiconductor device including at least one capacitor which is connected to a capacitive contact hole exposed on the surface of an interlayer insulating film. The capacitor includes a base-side lower electrode film having a hollow formed on the capacitive contact hole; a metal plug embedded in the lower portion of the hollow of the base-side lower electrode film; a top-side lower electrode film having a hollow-pillar shape, which is engaged with the upper portion of the hollow of the base-side lower electrode film; a dielectric film and an upper electrode film which are sequentially laminated so as to cover the peripheral surface of the base-side lower electrode film and the peripheral surface of the top-side lower electrode film as well as the interior surface of the top-side lower electrode film.

Due to the above structure of the semiconductor device, it is possible to increase the strengths of the base-side lower electrode film and the top-side lower electrode film; hence, it is possible to prevent the capacitor from being destroyed due to deficient strengths of electrodes during manufacturing.

A manufacturing method adapted to the semiconductor device includes a first step for forming a first sacrifice insulating film on the surface of the interlayer insulating film and for forming a first capacitor hole running through the first sacrifice insulating film so as to expose the capacitive contact plug therein; a second step for forming the base-side lower electrode film on the interior surface of the first capacitor hole and for embedding a metal plug in the first capacitor hole; a third step for performing etching-back on the surface of the first sacrifice insulating film so as to expose the peripheral surface of the base-side lower electrode film and for forming a side wall serving as an etching stopper on the peripheral surface of the base-side lower electrode film; a fourth step for forming a second sacrifice insulating film so as to cover the first sacrifice insulating film, the base-side lower electrode film, and the side wall; a fifth step for forming a second capacitor hole running through the second sacrifice insulating film by using the side wall as the etching stopper and for partially removing the metal plug exposed in the bottom of the second capacitor hole by way of etching, thus exposing the upper portion of the interior surface of the base-side lower electrode film; a sixth step for forming a top-side lower electrode film so as to cover the interior surface of the second capacitor hole and the upper portion of the interior surface of the base-side lower electrode film; a seventh step for removing the first sacrifice insulating film and the second sacrifice insulating film by way of wet etching, thus exposing the peripheral surface of the base-side lower electrode film and the peripheral surface of the top-side lower electrode film; and an eighth step for sequentially laminating a dielectric film and an upper electrode film so as to cover the peripheral surface of the base-side lower electrode film and the peripheral surface of the top-side lower electrode film as well as the interior surface of the top-side lower electrode film.

In the above manufacturing method, a plurality of side walls collectively serving as an etching stopper is formed in connection with a plurality of peripheral surfaces of a plurality of base-side lower electrode films so that at least one connection portion for connecting together the plurality of side walls is formed together with at least one gap portion, wherein an etching solution used for the wet etching for removing the first sacrifice insulating film and the second sacrifice insulating film is controlled to flow into the gap portion.

Due to the double processing, it is possible to form a large capacitor hole having a high aspect ratio and a high stability. It is possible to increase the strengths of the base-side and top-side lower electrode films by the remaining portion of the metal plug which remains due to partial etching; thus, it is possible to form the capacitor having high strengths of electrodes.

In result, it is possible to control the aspect ratio of the capacitor hole from being excessively increased in manufacturing; and it is possible to increase the capacitive electrode area in the semiconductor device.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross-sectional view used for explaining a first step of a manufacturing method of a semiconductor device in accordance with one embodiment of the present invention;

FIG. 2 is s cross-sectional view used for explaining a second step of the manufacturing method of the semiconductor device;

FIG. 3 is a cross-sectional view used for explaining a third step of the manufacturing method of the semiconductor device;

FIG. 4 is a cross-sectional view used for explaining a fourth step of the manufacturing method of the semiconductor device;

FIG. 5 is a plan view of the semiconductor device shown in FIG. 4;

FIG. 6 is s cross-sectional view used for explaining a fifth step of the manufacturing method of the semiconductor device;

FIG. 7 is a cross-sectional view used for explaining a sixth step of the manufacturing method of the semiconductor device;

FIG. 8 is a cross-sectional view used for explaining a seventh step of the manufacturing method of the semiconductor device;

FIG. 9 is s cross-sectional view used for explaining an eighth step of the manufacturing method of the semiconductor device;

FIG. 10 is a cross-sectional view used for explaining a ninth step of the manufacturing method of the semiconductor device;

FIG. 11 is a cross-sectional view used for explaining a tenth step of the manufacturing method of the semiconductor device;

FIG. 12 is a cross-sectional view of the semiconductor device;

FIG. 13 is a cross-sectional view used for explaining a first step of the foregoing manufacturing method of a semiconductor device;

FIG. 14 is a cross-sectional view used for explaining a second step of the foregoing manufacturing method of the semiconductor device; and

FIG. 15 is a cross-sectional view used for explaining a third step of the foregoing manufacturing method of the semiconductor device.

### DETAILED DESCRIPTION OF PREFERRED EMBODIMENT

The present invention will now be described herein with reference to illustrative embodiments. Those skilled in the art will recognize that many alternative embodiments can be accomplished using the teachings of the present invention and that the invention is not limited to the embodiments illustrated for explanatory purposes.

The illustrations are used to explain a semiconductor device and its manufacturing method in accordance with the present invention; hence, the sizes, thicknesses, and dimensions regarding layers, films, and components do not necessarily match the sizes, thicknesses, and dimensions of actual products of semiconductor devices.

### 1. Manufacturing Method

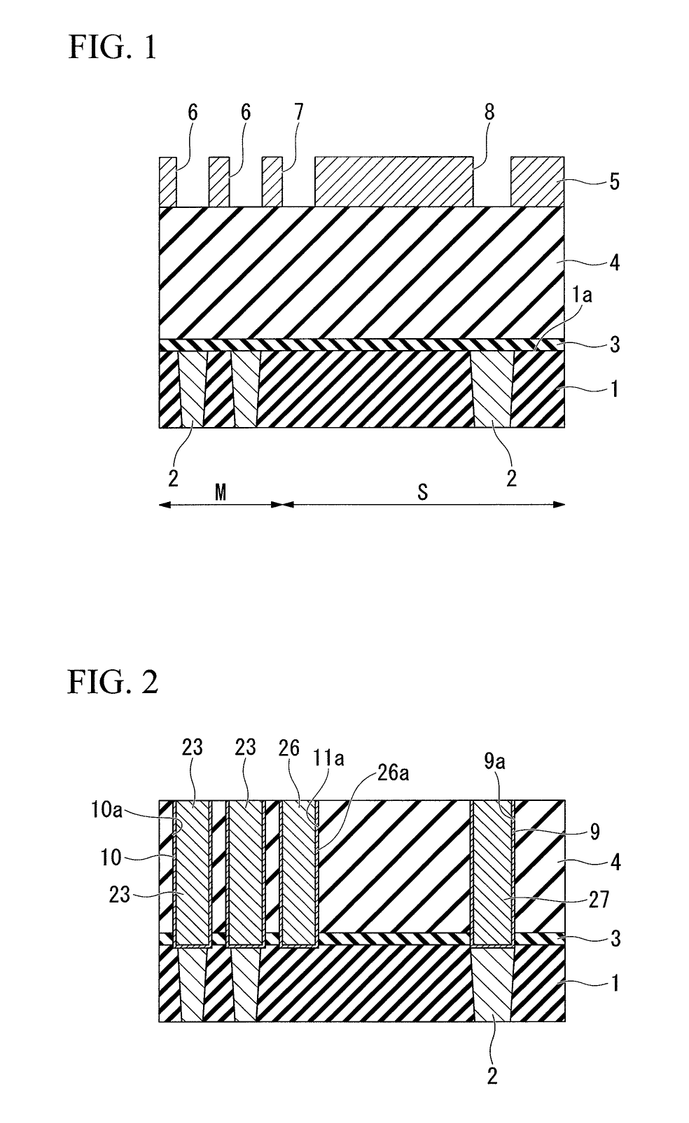

A manufacturing method of a semiconductor device according to one embodiment of the present invention will be described with reference to FIGS. 1 to 12.

The manufacturing method of the semiconductor device of the present embodiment includes a first step for forming a first sacrifice insulating film (used for forming a capacitor) on an interlayer insulating film and for forming a first capacitor hole in the first sacrifice insulating film, a second step for forming a base-side lower electrode film in the first capacitor hole and for embedding the first capacitor hole by use of a metal plug, a third step for performing etching-back on the surface of the first sacrifice insulating film and for forming a side wall (serving as an etching stopper) on the base-side lower electrode film, a third step for forming a second sacrifice insulating film, a fourth step for forming a second capacitor hole in the second sacrifice insulating film and for partially removing the metal plug via etching, a fifth step for forming a top-side lower electrode film covering the second capacitor hole and the base-side sacrifice insulating film, a sixth step for removing the first and second sacrifice insulating films via wet etching, and a seventh step for sequentially laminating a dielectric film and an upper electrode film.

The overall area of the semiconductor device, which is manufactured in accordance with the manufacturing method of the present embodiment, includes a memory cell region and a peripheral circuit region, wherein dynamic random-access memory (DRAM) elements constituted of capacitors and transistors are formed in the memory cell region.

Next, the details of the manufacturing method will be described below.

First, a first sacrifice insulating film 4 is formed on a surface la of an interlayer insulating film 1 on which a plurality of capacitive contact plugs 2 is exposed as shown in FIG. 1. As shown in FIG. 2, a plurality of first capacitor holes 10a is formed in the first sacrifice insulating film 4 so as to expose the capacitive contact plugs 2. In addition, a base-side lower electrode film 10 is formed on the interior surface of each first capacitor hole 10a; then, the first capacitor holes 10a are embedded using metal plugs 23.

Specifically, MOS (i.e. Metal Oxide Semiconductor) transistors, gate lines, and bit lines are formed on a semiconductor substrate (not shown), on which an interlayer insulating film (not shown) is further formed to cover them. The interlayer insulating film 1 shown in FIG. 1 is laminated on the interlayer insulating film of the semiconductor substrate. A plurality of contact holes (not shown) is formed in the interlayer insulating film 1 and the interlayer insulating film of the semiconductor substrate, thus exposing source regions and drain regions of MOS transistors. Then, the capacitive contact plugs 2 are formed in the contact holes together with other contact plugs (not shown).

Next, a silicon nitride film 3 (serving as an etching stopper) is formed on the surface la of the interlayer insulating film 1 on which the capacitive contact plugs 2 are exposed; then, the first sacrifice insulating film 4 composed of silicon oxide is formed on the silicon nitride film 3. The silicon nitride film 3 is formed with the thickness ranging from 30 nm to 100 nm in accordance with LP-CVD (i.e. Low-Pressure Chemical Vapor Deposition). The first sacrifice insulating film 4 is formed with the thickness ranging from 0.5 μm to 1.5 μm in accordance with plasma CVD, for example.

Next, as shown in FIG. 1, a photoresist layer 5 is formed on the first sacrifice insulating film 4. In addition, opening patterns 6 (used for the formation of the first capacitor holes 10a), an opening pattern 7 (used for the formation of a partition channel 11a for portioning the memory cell region M and the peripheral circuit region S), and an opening pattern 8 (used for the formation of a contact hole 9a in the peripheral circuit) are formed in the photoresist layer 5 by way of lithography.

Next, as shown in FIG. 2, plasma dry etching is performed using a mask (corresponding to the photoresist layer 5 having the opening patterns 6, 7, and 8) so as to form the contact hole 9a, the first capacitor holes 10a, and the partition channel 11a in the first sacrifice insulating film 4 and the silicon nitride film 3, thus exposing the capacitive contact holes 2.

Next, the photoresist layer 5 is removed; then, the base-side lower electrode films 10 composed of TiN are formed on the interior surfaces of the first capacitor holes 10a with the thickness ranging from 5 nm to 20 nm in accordance with thermal CVD using TiCl₄ gas. At the same time, a barrier film 26a composed of TiN is formed on the interior surface of the partition channel 11a with the thickness ranging from 5 nm to 20 nm. In addition, a barrier film 9 composed of TiN is formed on the interior surface of the contact hole 9a with the thickness ranging from 5 nm to 20 nm.

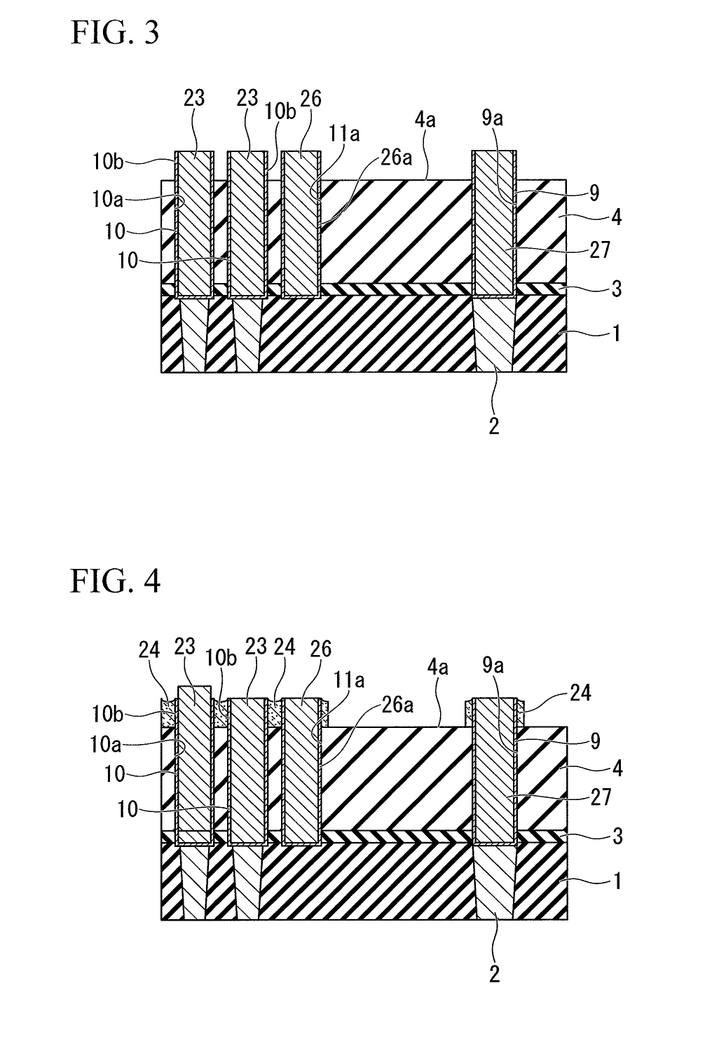

Thereafter, a metal film composed of tungsten is formed on the first sacrifice insulating film 4 so as to embed the contact hole 9a, the first capacitor holes 10a, and the partition channel 11a; then as shown in FIG. 3, it is removed from the first sacrifice insulting film 4 by way of CMP (chemical Mechanical Polishing), thus embedding the first capacitor holes 10a with metal plugs 23 composed of tungsten while embedding the contact hole 9a with a tungsten plug 27. In addition, a tungsten plug 26 is embedded in the partition channel 11a.

Next, etching-back is performed on a surface 4a of the first sacrifice insulating film 4 so as to expose upper peripheral portions 10b of the base-side lower electrode films 10. In addition, side walls 24 (collectively serving as an etching stopper) are formed in connection with the upper peripheral portions 10b of the base-side lower electrode films 10.

Specifically, as shown in FIG. 3, wet etching is performed on the surface 4a of the first sacrifice insulating film 4 with the etched thickness ranging from 30 nm to 100 nm. This makes it possible to expose the upper peripheral portions 10b of the base-side lower electrode films 10. The upper peripheral portions 10b of the base-side lower electrode films 10 are exposed while covering the metal plugs 23.

At the same time, the upper peripheral portions of the barrier films 9 and 26a are also exposed while covering the tungsten plugs 26 and 27.

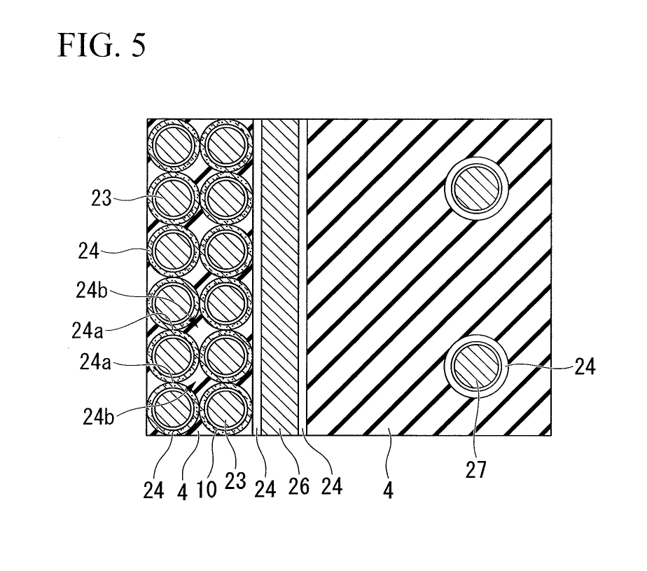

Next, as shown in FIG. 4, a silicon nitride film (not shown) is formed on the first sacrifice insulating film 4 with the thickness ranging from 10 nm to 60 nm in accordance with LP-CVD; then, it is subjected to etching-back so as to form the side walls 24 composed of silicon nitride in connection with the upper peripheral portions of the base-side lower electrode films 10 and the upper peripheral portions of the barrier films 9 and 26a. At this time, as shown in FIG. 5, the side walls 24 are formed to surround the base-side lower electrode films 10 which mutually adjoin together, wherein the adjacent side walls 24 are connected via connection portions 24a, while gap portions 24b are formed in the area excluding the connection portions 24a. That is, the side walls 24 are formed not to completely cover the base-side lower electrode films 10 but to form gaps therebetween. This makes it possible for an etching solution to infiltrate into the lower portions of the side walls 24 during the execution of wet etching to remove the first sacrifice insulating film 4 and a second sacrifice insulating film 13 in the latter process.

Next, the second sacrifice insulating film 13 is formed to cover the first sacrifice insulating film 4, the base-side lower electrode films 10, and the side walls 4.

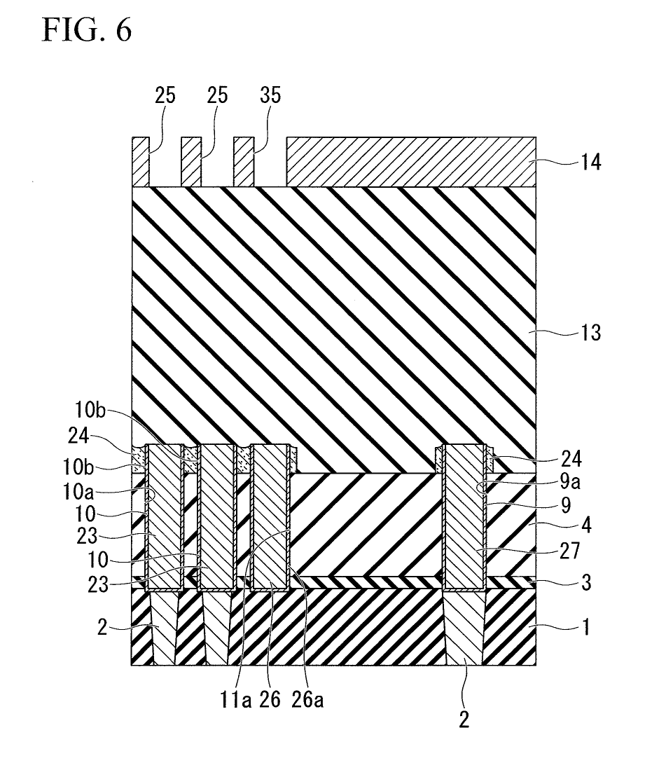

Specifically, as shown in FIG. 6, the second sacrifice insulating film 13 composed of silicon oxide is formed with the thickness ranging from 0.8 μm to 1.5 μm in accordance with plasma CVD in such a way that all the first sacrifice insulating film 4, the base-side lower electrode films 10, and the side walls 4 are completely covered with the second sacrifice insulating film 13. In addition, a photoresist layer 14 is formed on the second sacrifice insulating film 13; then, opening patterns 25 (used for the formation of the first capacitor holes 10a) and an opening pattern 35 (used for the formation of the partition channel 11a) are applied to the photoresist layer 14 by way of lithography.

Next, a plurality of second capacitor holes 13a is formed in the second sacrifice insulating film 13 by use of the etching stopper (corresponding to the side walls 24). In addition, the metal plugs 23 which are exposed in the bottoms of the second capacitor holes 13a are partially removed by way of etching, thus exposing upper interior portions 10c of the base-side lower electrode films 10.

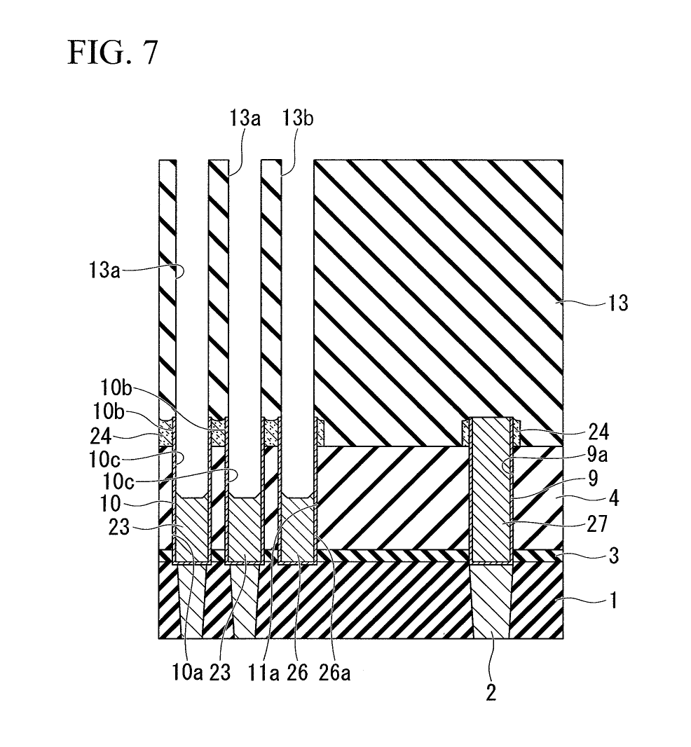

Specifically, as shown in FIG. 7, plasma dry etching is performed using the photoresist layer 14 having the opening patterns 25 and 35 so as to form the second capacitor holes 13a and the a partition channel 13b. As an etching device, it is possible to use a parallel-plate double-frequency dry etching device, for example. As etching gas, it is possible to use C₄F₆ gas, C₄F₈ gas, argon gas, and oxygen gas, for example. In this case, the side walls 24, the metal plugs 23 (composed of tungsten), tungsten plug 26, the base-side lower electrode films 10 (composed of TiN), and the barrier film 26a collectively serve as an etching stopper, which is a structure for preventing etching from progressing excessively irrespective of alignment deviations. However, when the base-side lower electrode films 10 (composed of TiN) have large exposed areas, depositions composed of TiN, which are difficult to be removed, may be attached to the interior surfaces of the second capacitor holes 13a, thus causing defects in manufacturing. To avoid such a phenomenon, it is preferable that the metal plugs 23 (composed of tungsten) be embedded inside TiN materials in advance.

Next, after removal of the photoresist layer 14, plasma dry etching using SF₆ is performed so as to partially remove the metal plugs 23 and the tungsten plug 26, thus exposing the upper interior portions 10c of the base-side lower electrode films 10 and the upper interior portion of the barrier film 26a. By removing the metal plugs 23 and the tungsten plug 26 while remaining prescribed portions thereof, it is possible to improve the strength of the base-side lower electrode films 10. This prevents capacitors from being destroyed due to the lack of adequate strength. Herein, as an etching device, it is possible to use a dry etching device using an inductive-coupling plasma source in prescribed conditions, i.e. pressure ranging from 4 mTorr to 20 mTorr, SF₆ flow ranging from 100 sccm to 500 sccm, stage temperature ranging from 0° C. to 40° C., source power ranging from 500 W to 2000 W, and bias power ranging from 30 W to 100 W, for example.

Next, top-side lower electrode films 15 are formed to cover the interior surfaces of the second capacitor holes 13a and the upper interior portions 10c of the base-side lower electrode films 10.

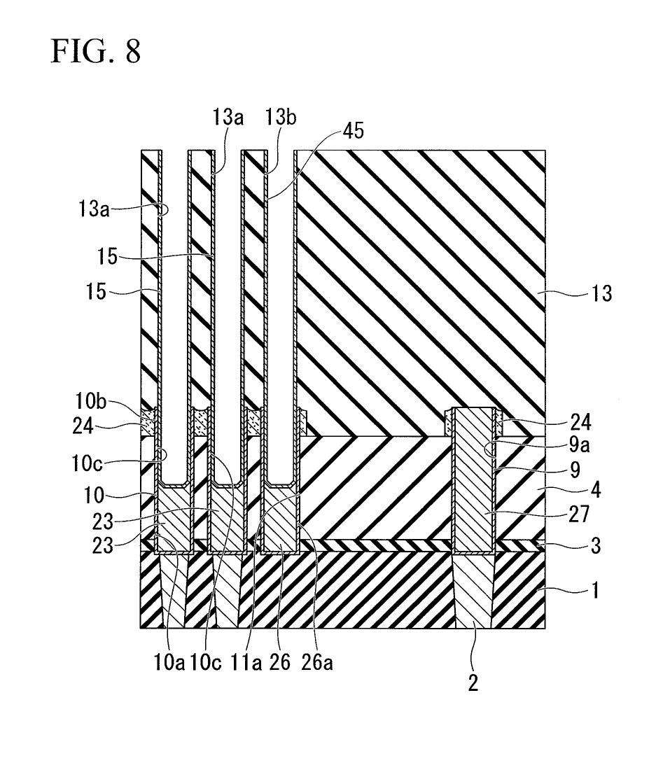

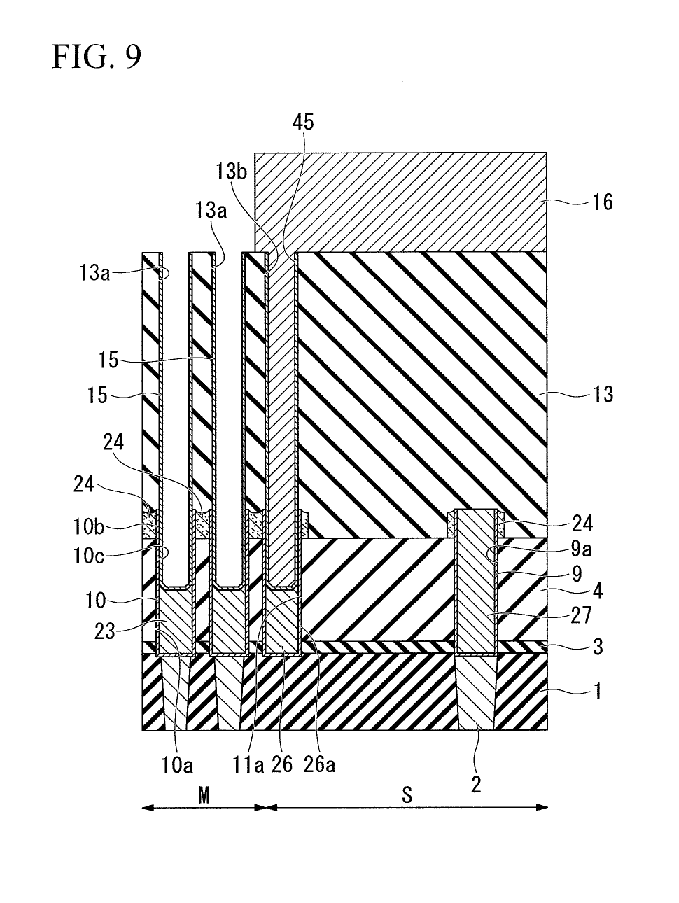

Specifically, as shown in FIG. 8, the top-side lower electrode films 15 composed of TiN are formed to cover the interior surfaces of the second capacitor holes 13a and the upper interior portions 10c of the base-side lower electrode films 10 with the thickness ranging from 10 nm to 30 nm. As shown in FIG. 9, the surface of the second sacrifice insulating film 13 is covered with a TiN film 45. In addition, the interior surface of the partition channel 13b is covered with the TiN film 45 as well. Since the metal plugs 23 composed of tungsten are covered with the top-side lower electrode films 15, only the TiN film is exposed on the interior surface of the top-side lower electrode films 15, on which no tungsten is exposed. Then, dry etching is performed to remove the TiN film from the second sacrifice insulating film 13.

Next, the first sacrifice insulating film 4 and the second sacrifice insulating film 13 are removed by way of wet etching, thus exposing peripheral surfaces 10d of the base-side lower electrode films 10 and peripheral surfaces 15a of the top-side lower electrode film 15.

Specifically, as shown in FIG. 9, a photoresist layer 16 is formed on the second sacrifice insulating film 13 in the peripheral circuit region S. The photoresist layer 16 is formed to embed the partition channel 13b for partitioning the memory cell region M and the peripheral circuit region S.

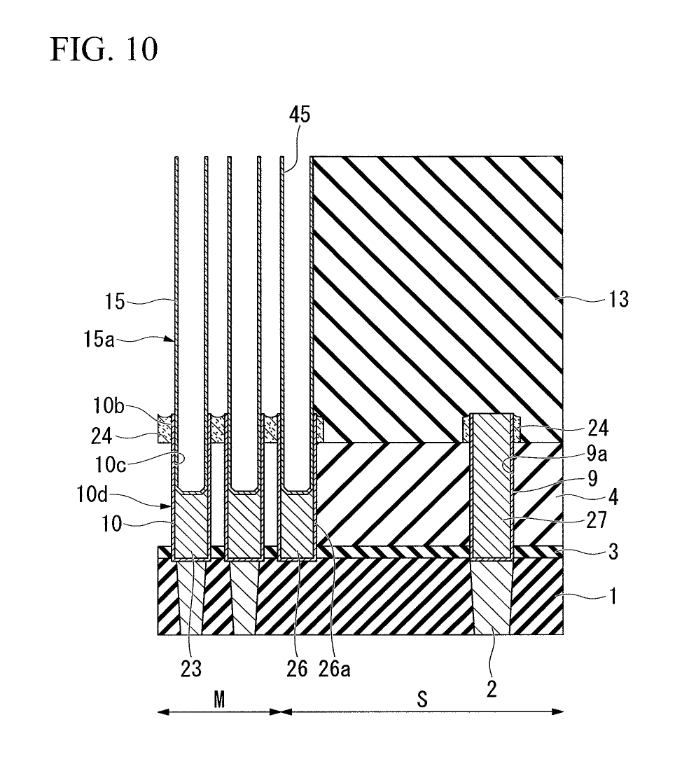

Next, as shown in FIG. 10, wet etching is performed using dilute hydrofluoric acid so as to remove the first sacrifice insulating film 4 and the second sacrifice insulating film 13, both of which are composed of silicon oxide. Herein, only the prescribed portions of the first and second sacrifice insulating films 4 and 13 belonging to the memory cell region M are moved, while the other portions belonging to the peripheral circuit region S are protected by the photoresist layer 16.

Although the interlayer insulating film 1 is composed of silicon oxide in a similar manner to the first sacrifice insulating film 4 and the second sacrifice insulating film 13, the silicon nitride film 3 (deposited on the interlayer insulating film 1) serves as an etching stopper so as to protect the interlayer insulating film 1 from etching. Similarly, the side walls 24 remain irrespective of etching, thus preventing the base-side lower electrode films 10 from adjoining in contact with the each other.

Due to the gap portions 24b between the side walls 24 as shown in FIG. 5, a hydrofluoric acid flows through the gap portions 24b so as to affect the first sacrifice insulating film 4, which is thus removed by way of wet etching.

As described above, it is possible to expose both the peripheral surfaces 10d of the base-side lower electrode films 10 and the peripheral surfaces 15a of the top-side lower electrode films 15.

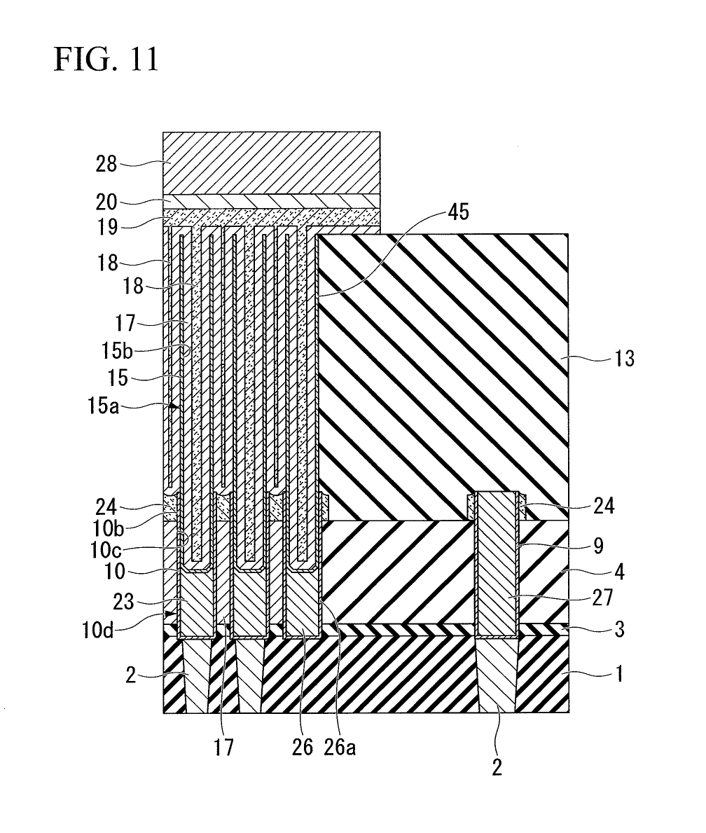

Next, dielectric films 17 and upper electrode films 18 (see FIG. 11) are sequentially formed to cover the peripheral surfaces 10d of the base-side lower electrode films 10 and the peripheral surfaces 15a of the top-side lower electrode films 15 as well as interior surfaces 15b of the top-side lower electrode film 15.

Specifically, as shown in FIG. 11, the dielectric films 17 and the upper electrode films 18 (composed of TiN) are sequentially laminated to cover the peripheral surfaces 10d of the base-side lower electrode films 10 and the peripheral surfaces 15a of the top-side lower electrode films 15 as well as the interior surfaces 15b of the top-side lower electrode films 15. In addition, an upper electrode polysilicon film 19 and an upper electrode tungsten film 20 are sequentially formed. The upper electrode polysilicon film 19 and the upper electrode tungsten film 20 are subjected to patterning using a mask (corresponding to a photoresist layer 28).

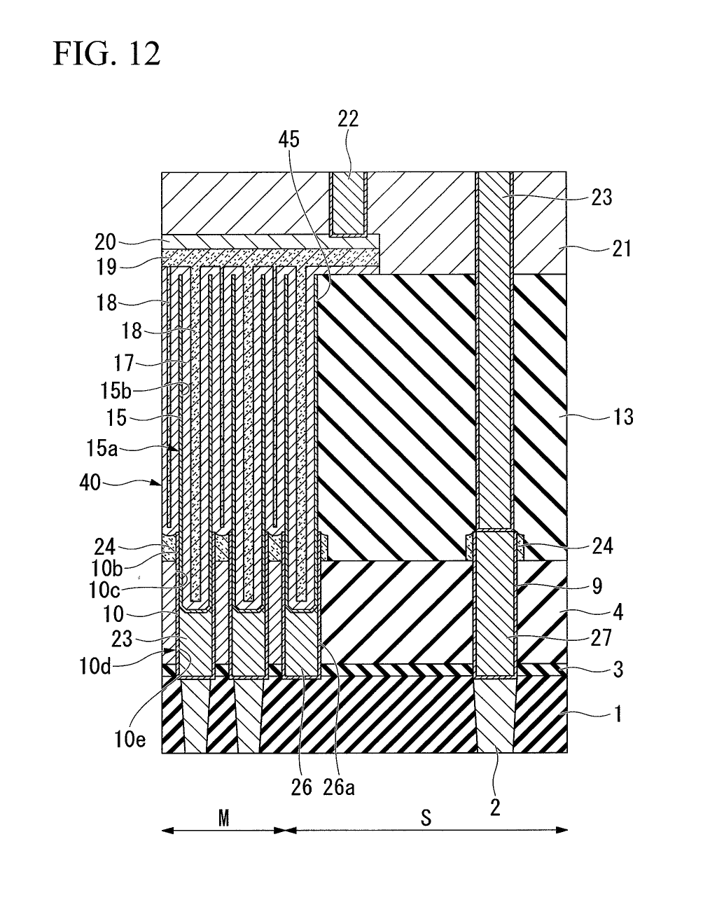

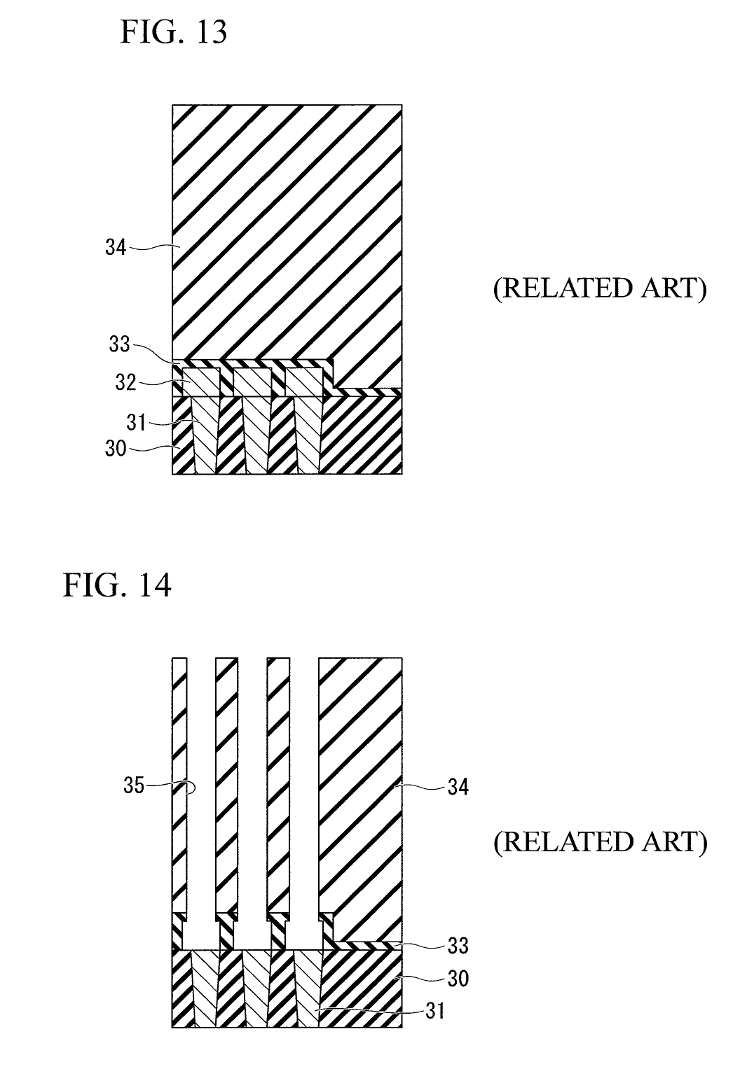

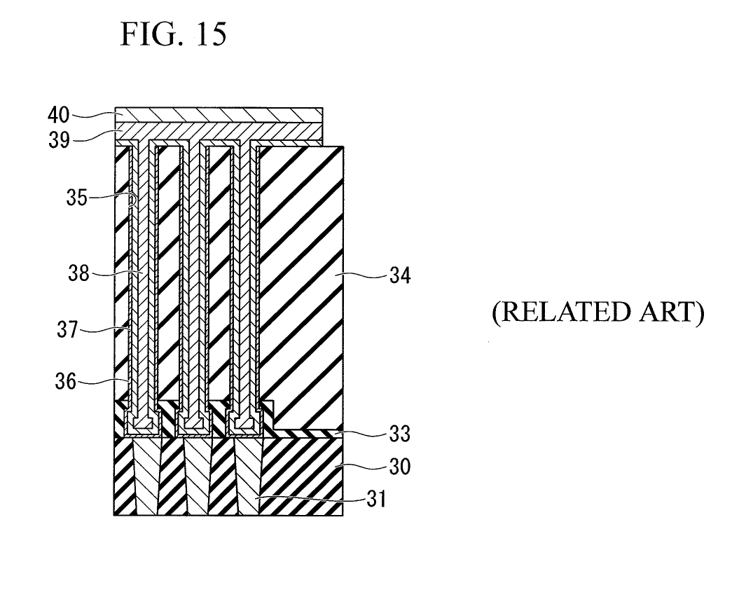

By way of the above process, it is possible to form capacitors 40 (see FIG. 12) constituted of the base-side lower electrode films 10, the top-side lower electrode films 15, the dielectric films 17, and the upper electrode films 18.

Thereafter, as shown in FIG. 12, after removable of the photoresist layer 28, an interlayer insulating film 21 is formed on the entire surface including the memory cell region M and the peripheral circuit region S, thus forming a contact plug 22 (which is connected to the upper electrode tungsten film 20) and a contact plug 23 (which is connected to the tungsten plug 27).

The above completes the production of a semiconductor device of FIG. 12 having the capacitors 40.

### 2. Semiconductor Device

FIG. 12 shows the semiconductor device of the present embodiment having capacitors 40 which are formed on the surface la of the interlayer insulating film 1 on which the surfaces of the capacitive contact plugs 2 are exposed. The semiconductor device of the present embodiment includes the memory cell region M and the peripheral circuit region S, wherein a plurality of DRAM elements configured by capacitors 40 and transistors (not shown) is formed in the memory cell region M.

FIG. 12 omits an illustration in which an interlayer insulating film is formed to cover MOS transistors, gate lines, and bit lines formed on a semiconductor substrate, wherein the interlayer insulating film 1 is laminated with the above interlayer insulating film. A plurality of contact holes (not shown) are formed in the interlayer insulating film 1 and the interlayer insulating film formed on the semiconductor substrate so as to expose source regions and drain regions of MOS transistors. The capacitive contact plugs 2 and other contact plugs (not shown) are formed inside the contact holes.

The capacitors 40 are connected to MOS transistors via the capacitive contact plugs 2. The capacitors 40 are constituted of the base-side lower electrode films 10 of hollow-pillar shapes having hollows 10e formed on the capacitive contact plugs 2, the metal plugs 23 embedded in the hollows 10e of the base-side lower electrode films 10, the top-side lower electrode films 15 of hollow-pillar shapes which are engaged with the upper portions of the hollows 10e of the base-side lower electrode films 10, the dielectric films 17 and the upper electrode films 18 which are sequentially laminated together so as to cover the peripheral surfaces 10d of the base-side lower electrode films 10 and the peripheral surfaces 15a of the top-side lower electrode films 15 as well as the interior surfaces 15b of the top-side lower electrode films 15, and the side walls 24 which are formed in connection with the upper peripheral portions 10b of the base-side lower electrode films 10 so as to connect the base-side lower electrode films 10 adjoining together.

The silicon nitride film 3 is formed on the interlayer insulating film 1. The upper electrode polysilicon film 19 and the upper electrode tungsten film 20 are sequentially formed on the capacitors 40. The first sacrifice insulating film 4 and the second sacrifice insulating film 13 still remain in the peripheral circuit region S, thus forming laminated interlayer insulating films. The tungsten plug 27 and the contact plug 23 runs through the first and second sacrifice insulating films 4 and 13.

According to the manufacturing method of the semiconductor device of the present embodiment, the first capacitor holes 10a are formed in the first sacrifice insulating film 4, and the second capacitor holes 13a are formed in the second sacrifice insulating film 13; therefore, it is possible to form a plurality of capacitors holes having high aspect ratios by way of two steps of manufacturing. Since the metal plugs 23 are partially etched, the remaining portions of the metal plugs 23 reinforce the base-side lower electrode films 10 and the top-side lower electrode films 15, thus forming the capacitors 40 having electrodes of superior strengths.

Since the side walls 24 are collectively used as an etching stopper during the formation of the second capacitor holes 13a, they form a self-alignment structure in partially etching the metal plugs 23 after the formation of the second capacitor holes 13a. This achieves the precise positioning between the first capacitor holes 10a and the second capacitor holes 13a with ease.

According to the manufacturing method of the semiconductor device of the present embodiment, the adjacent side walls 24 are connected together by way of the connection portions 24a which are formed simultaneously with the gap portions 24b therebetween, wherein an etching solution is controlled to flow into the gap portions 24b during wet etching to remove the first and second sacrifice insulating films 4 and 13, it is possible to easily remove the first sacrifice insulating film 4 in particular.

Due to the formation of the connection portions 24a for connecting the adjacent side walls 24, it is possible to prevent the capacitors 40 from being destroyed because the capacitors 40 have a high stability during manufacturing.

The manufacturing method is characterized in that the tungsten plug 27 is formed in the peripheral circuit region S during the formation of the base-side lower electrode films 10. This eliminates the necessity of providing an additional step for forming the tungsten plug 27.

In the semiconductor device of the present embodiment, the metal plugs 23 are embedded in the lower portions of the hollows 10e of the base-side lower electrode films 10, while the top-side lower electrode films 15 having hollow-pillar shapes are engaged with the upper portions of the hollows 10e of the base-side lower electrode films 10. This improves the strengths of the base-side lower electrode films 10 and the top-side lower electrode films 15, thus preventing the capacitors 40 from being destroyed due to deficient strengths of electrodes.

Since the dielectric films 17 and the upper electrode films 18 are sequentially laminated together so as to cover the peripheral surfaces 10d of the base-side lower electrode films 10 as well as the peripheral surfaces 15a and the interior surfaces 15b of the top-side lower electrode films 15, it is possible to secure a relatively large electrode surface with respect to the base-side and top-side lower electrode films 10 and 15, thus increasing the electrostatic capacitances of the capacitors 40.

Due to the formation of the side walls 24 for connecting together the adjacent base-side lower electrode films 10, it is possible to reliably prevent the capacitors 40 from being destroyed in manufacturing.

Lastly, it is apparent that the present invention is not limited to the above embodiment, but may be modified and changed without departing from the scope and spirit of the invention.

What is claimed is:

1. A semiconductor device including at least one capacitor which is connected to a capacitive contact hole exposed on a surface of an interlayer insulating film, wherein the capacitor includes
a base-side lower electrode film having a hollow formed on the capacitive contact hole;
a metal plug embedded in a lower portion of the hollow of the base-side lower electrode film;
a top-side lower electrode film having a hollow-pillar shape, which is engaged with an upper portion of the hollow of the base-side lower electrode film; and
a dielectric film and an upper electrode film which are sequentially laminated so as to cover a peripheral surface of the base-side lower electrode film and a peripheral surface of the top-side lower electrode film as well as an interior surface of the top-side lower electrode film.

2. The semiconductor device according to claim 1 further comprising a side wall which is formed in connection with the peripheral surface of the base-side lower electrode film to connection with an adjacent base-side lower electrode film.

3. A semiconductor device comprising:
a first interlayer insulating film formed above a semiconductor substrate;
a first electrode pierced through the first interlayer insulating film;
a first dielectric film formed above the first interlayer insulating film;
a contact hole pierced through the first dielectric film;
a second electrode formed in a part of the contact hole, the second electrode being electrically contacted with the first electrode;
a third electrode formed in the rest of the contact hole and having a top portion higher than a surface of the first dielectric film, the third electrode being electrically contacted with the second electrode; and
a second dielectric film formed on both the inside and outside of the third electrode.

4. The semiconductor device according to claim 3 further comprising a fourth electrode which is formed on the first electrode so as to cover a side surface of the second electrode and to cover a part of a side surface of the third electrode.

5. The semiconductor device according to claim 3 further comprising a first side wall formed on the first dielectric film.

6. The semiconductor device according to claim 3, wherein the first electrode is a cylindrical structure, the second electrode is a cylindrical structure, and the third electrode is a hollow cylindrical structure.

7. The semiconductor device according to claim 4 wherein the first electrode is a cylindrical structure, the second electrode is a cylindrical structure, the third electrode is a hollow cylindrical structure, and the fourth electrode is a hollow cylindrical structure.

8. The semiconductor device according to claim 3 further comprising:
a second interlayer insulating film which is formed above the first interlayer insulating film and whose top portion shares a top portion of the first dielectric film;
a third interlayer insulating film which is formed on the second interlayer insulating film and whose top portion shares a top portion of the third electrode; and
a fourth interlayer insulating film mounted on the third interlayer insulating film.

9. The semiconductor device according to claim 4 further comprising:
a fifth electrode pierced through the first interlayer insulating film;
a sixth electrode which is pierced through the second interlayer insulating film and a part of the third interlayer insulating film and which has an electric contact with the fifth electrode; and
a seventh electrode which is pierced through the rest of the third interlayer insulating film and the fourth interlayer insulating film and which has an electric contact with the sixth electrode.

10. The semiconductor device according to claim 9 further comprising:
an eighth electrode for covering a bottom portion and a side portion of the sixth electrode; and
a ninth electrode for covering a top portion and a side portion of the seventh electrode.

11. A semiconductor device comprising:
a first interlayer insulating film formed above a semiconductor substrate;
a first electrode which is formed in the first interlayer insulating film and whose height is lower than a top surface of the first interlayer insulating film;
a second electrode which is formed above the first electrode and which has a first potion electrically connected to a top portion of the first electrode and a second portion having a hollow cylindrical structure elongated from the first portion; and
a first dielectric film formed on an inner surface and an outer surface of the second electrode.

12. The semiconductor device according to claim 11 further comprising a third electrode which is formed between a side surface of the first electrode and the first dielectric film and which is formed between the second electrode and the first dielectric film.

13. The semiconductor device according to claim 11 further comprising a first side wall formed on the first dielectric film.

14. The semiconductor device according to claim 13, wherein a part of the third electrode is formed on a bottom portion of the first electrode.

15. The semiconductor device according to claim 12, wherein the third electrode has a top portion which is higher than the top surface of the first dielectric film.

16. The semiconductor device according to claim 15 further comprising a first side wall formed on a side surface of the third electrode, which protrudes from the top surface of the first dielectric film.

17. The semiconductor device according to claim 16 further comprising a plurality of capacitors having the first electrode, the second electrode, the third electrode, and the fourth electrode, wherein the first side wall is formed in an area lying between the first electrode, the second electrode, the third electrode, and the fourth electrode which are adjacent to each other.

18. The semiconductor device according to claim 11 further comprising an upper electrode which is formed in the third electrode via the first dielectric film so as to form a capacitor, which has the upper electrode and a lower electrode corresponding to the first electrode, the second electrode, the third electrode, and the fourth electrode.
